(19) United States
(12) Patent Application Publication
(10) Pub. No.: US 2012/0228768 A1
(43) Pub. Date: Sep. 13, 2012

(54) INTEGRATED CIRCUIT PACKAGING SYSTEM USING B-STAGE POLYMER AND METHOD OF MANUFACTURE THEREOF

(76) Inventors: Reza Argenty Pagaila, Singapore (SG); Soo Jung Park, Icheon-si (KR); HeeJo Chi, Ichon-si (KR)

(21) Appl. No.: 13/042,457

(22) Filed: Mar. 7, 2011

(51) Int. Cl. H01L 23/488; H01L 21/60

(52) U.S. Cl. 257/738; 438/119; 257/E21.514; 257/E23.023

(57) ABSTRACT

An integrated circuit packaging system and method of manufacture thereof includes: a substrate having a bond pad; a B-stage polymer, having a dispersion of conductive particles therein, on the bond pad; and a bond ball inserted into the B-stage polymer for forming intermetallic structures between the bond ball and the bond pad.

### TECHNICAL FIELD

The present invention relates generally to an integrated circuit packaging system, and more particularly to a system for bonding dies and packages.

### BACKGROUND ART

Ongoing goals of the electronics industry are increased miniaturization of components, greater packaging density of integrated circuits (“ICs”), higher performance, and lower cost. Semiconductor package structures continue to advance toward miniaturization, to increase the density of the components that are packaged therein while decreasing the sizes of the products that are made using the semiconductor package structures. This is in response to continually increasing demands on information and communication products for ever-reduced sizes, thicknesses, and costs, along with ever-increasing performance.

These increasing requirements for miniaturization are particularly noteworthy, for example, in portable information and communication devices such as cellular phones, hands-free cellular phone headsets, personal data assistants (“PDA's”), camcorders, notebook computers, and so forth. All of these devices continue to be made smaller and thinner to improve their portability. Accordingly, large-scale IC (“LSI”) packages that are incorporated into these devices are required to be made smaller and thinner. The package configurations that house and protect LSI require them to be made smaller and thinner as well.

Different challenges arise from increased functionality integration and miniaturization. For example, a semiconductor product having increased functionality may be made smaller but may still be required to provide a large number of inputs/outputs (I/O). The semiconductor product also needs to be readily testable while still providing smaller size. Further, increased performance of semiconductor product put additional challenges on the semiconductor product during test and in the field.

Among the problems encountered is how to control the various temperatures that dies and packages are subject to during the process of manufacture. This is referred to as thermal budget. It is desirable and necessary to have a low thermal budget in order to increase the reliability of integrated circuits. Integrated circuits are made by doping impurities into silicon or other substrate materials and each application of heat causes migration of the dopants from their desired locations resulting in shorted life expectancy.

Another problem is that more advanced devices use low dielectric constant, low-K, materials as insulators, and these materials are soft or porous compared to traditional materials. This means that bonding forces must be low in order to reduce damage to the low-K materials.

A further problem is the need to reduce cost. Gold is often used in die and package bonding wires, but it is extremely expensive. Copper is a lower cost replacement to gold, however, copper bonding must be performed in an inert atmosphere because copper oxidizes easily and copper oxide acts as an insulator preventing the formation of reliable conductive bonds. Thus, the processing and capital equipment costs associated with performing operations in an inert atmosphere diminishes the cost savings offered by copper.

Further, copper bonding normally requires high bonding forces to obtain good bonding, which often results in damage to low-K materials. In some cases, aluminum plated bond pads may be used with copper bonding to reduce the need for high bonding forces, but this tends to increase cost.

Thus, it is increasingly critical that answers be found to these problems. In view of the ever-increasing commercial competitive pressures, along with growing consumer expectations and the diminishing opportunities for meaningful product differentiation in the marketplace, it is critical that answers be found for these problems. Additionally, the need to reduce costs, improve efficiencies and performance, and meet competitive pressures adds an even greater urgency to the critical necessity for finding answers to these problems.

Solutions to these problems have been long sought but prior developments have not taught or suggested any solutions and, thus, solutions to these problems have long eluded those skilled in the art.

### DISCLOSURE OF THE INVENTION

The present invention provides a method of manufacture of an integrated circuit packaging system including: providing a substrate having a bond pad; depositing a B-stage polymer, having a dispersion of conductive particles therein, on the bond pad; inserting a bond ball into the B-stage polymer; and forming intermetallic structures between the bond ball and the bond pad.

The present invention provides an integrated circuit packaging system, including: a substrate having a bond pad; a B-stage polymer, having a dispersion of conductive particles therein, on the bond pad; and a bond ball inserted into the B-stage polymer for forming intermetallic structures between the bond ball and the bond pad.

Certain embodiments of the invention have other steps or elements in addition to or in place of those mentioned above. The steps or elements will become apparent to those skilled in the art from a reading of the following detailed description when taken with reference to the accompanying drawings.

### BRIEF DESCRIPTION OF THE DRAWINGS

FIG. 1 is a cross-sectional view of a portion of an integrated circuit packaging system in a preparatory stage of bonding in an embodiment of the present invention.

FIG. 2 is a close up view of a portion of FIG. 1.

FIG. 3 is a cross-sectional view of FIG. 2 in a completed stage of bonding.

FIG. 4 is a close up view of a portion of FIG. 3.

FIG. 5 is a cross-sectional view of a completed integrated circuit packaging system in the embodiment of the present invention.

FIG. 6 is a flow chart of a method of manufacture of an integrated circuit packaging system in an embodiment of the present invention.

### BEST MODE FOR CARRYING OUT THE INVENTION

The following embodiments are described in sufficient detail to enable those skilled in the art to make and use the invention. It is to be understood that other embodiments would be evident based on the present disclosure, and that system, process, or mechanical changes may be made without departing from the scope of the present invention.

In the following description, numerous specific details are given to provide a thorough understanding of the invention. However, it will be apparent that the invention may be practiced without these specific details. In order to avoid obscuring the present invention, some well-known circuits, system configurations, and process steps are not disclosed in detail.

The drawings showing embodiments of the system are semi-diagrammatic and not to scale and, particularly, some of the dimensions are for the clarity of presentation and are shown exaggerated in the drawing FIGs. Similarly, although the views in the drawings for ease of description generally show similar orientations, this depiction in the FIGs. is arbitrary for the most part. Generally, the invention can be operated in any orientation.

For expository purposes, the term “horizontal” as used herein is defined as a plane parallel to the plane or surface of the substrate, regardless of its orientation. The term “vertical” refers to a direction perpendicular to the horizontal as just defined. Terms, such as “above”, “below”, “bottom”, “top”, “side” (as in “sidewall”), “higher”, “lower”, “upper”, “over”, and “under”, are defined with respect to the horizontal plane, as shown in the figures. The term “on” means that there is direct contact between elements.

The term “processing” as used herein includes deposition of material or photoresist, patterning, exposure, development, etching, cleaning, and/or removal of the material or photoresist as required in forming a described structure.

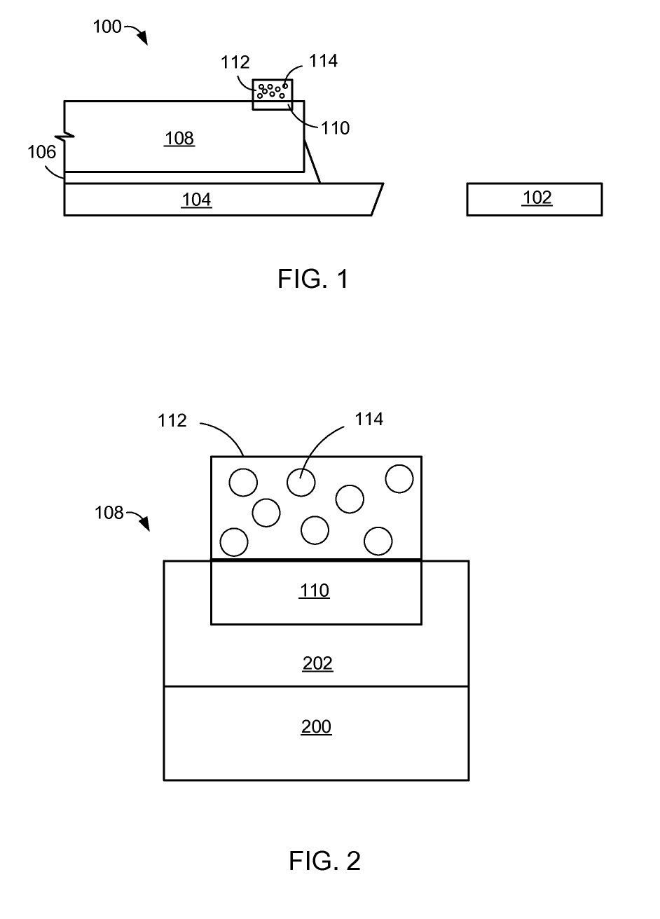

Referring now to FIG. 1, therein is shown a cross-sectional view of a portion of an integrated circuit packaging system in a preparatory stage of bonding in an embodiment of the present invention.

A portion of an integrated circuit packaging system 100 has a lead 102 spaced from a die attach paddle 104. A die attach adhesive 106 is deposited on the die attach paddle 104 to secure a die 108 thereto. The die 108 has a bond pad 110 embedded therein.

A B-stage polymer 112 with a dispersion of anisotropic conductive particles is deposited on the bond pad 110.

Referring now to FIG. 2, therein is shown a close up view of a portion of FIG. 1.

The die 108 includes a substrate 200 and a dielectric layer 202 in which the bond pad 110 is disposed.

The substrate 200 can be a semiconductor substrate, such as silicon or gallium arsenide, and may be a wafer level substrate prior to wafer dicing or after the die 108 is mounted on the die attach paddle 104, as shown in FIG. 1.

The dielectric layer 202 can be an insulating layer, such as silicon dioxide or a low dielectric constant, low-K, material having a dielectric constant under 2.0.

It will be understood that embodiments of the present invention can be used with bond pads on laminate, ceramic, or other substrates, or even on a substrate formed as a leadframe.

The bond pad 110 can be of any conductive material connected to the vias (not shown) in the dielectric layer 202. For cost reasons, the bond pad 110 is generally formed from copper.

The B-stage polymer 112 may be one of a number of B-stage polymers available from 3M Corporation of St. Paul, Minn. The B-stage polymer 112 may be an epoxy acrylate blend polymer that reaches a B-stage under an ultra-violet radiation dosage of 0.7 J/cm² (Joules per square centimeter) UVA or 0.5 J/cm² UVB or a thermal cure from about 45 to 60 minutes at 150° C.

In the B-stage, the material has a rubbery but penetrable consistency where objects may be inserted into the material and have the material flow around the objects without losing its as deposited shape.

The B-stage polymer 112, with the dispersion of anisotropic conductive particles 114, has a glass transition temperature between about −40° C. and 175° C. The anisotropic conductive particles 114 can be of materials such as silver, platinum, or tin coated beads.

The B-stage polymer 112 and the anisotropic conductive particles 114 may be deposited by a low temperature stencil or screening process.

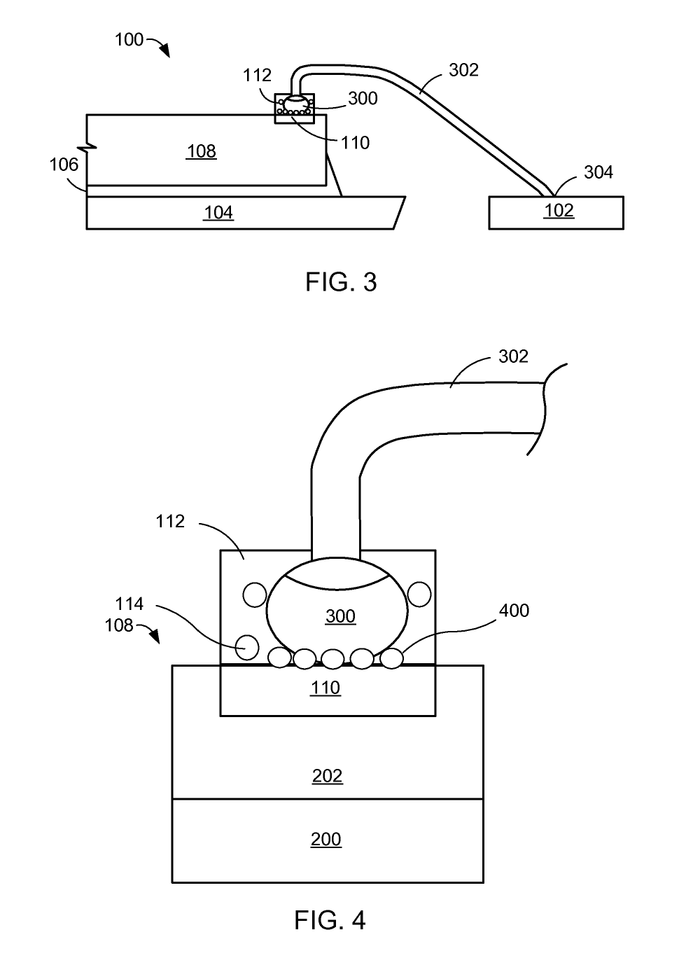

Referring now to FIG. 3, therein is shown a cross-sectional view of FIG. 2 in a completed stage of bonding.

A ball bond 300 is immersed in the B-stage polymer 112. A bond wire 302 connects the ball bond 300 to the lead 102 by a stitch bond 304. The wire bonding can be either from the B-stage polymer 112 to the lead 102 or vice versa in reverse stitch stand-off bumping process. The bond wire 302 is generally of copper, but it also may be brass, silver, aluminum, or nickel.

Referring now to FIG. 4, therein is shown a close up view of a portion of FIG. 3.

The B-stage polymer 112 has brought above its transition temperature, T_{g}, to be penetrable but still solid for insertion of the ball bond 300. During wire bonding, both the ball bond 300 and the bond pad 110 are placed at an elevated temperature, which is still under the melting point of the B-stage polymer 112 when ultra-sonic agitation is applied to the ball bond 300. The heat and friction causes the formation of intermetallic structures 400, which will be “sandwiched” between the ball bond 300 and the bond pad 110 in a process comparable to welding.

It has been discovered that the B-stage polymer 112 prevents oxidation of a copper ball bond during the formation of the intermetallic structure 400 from the anisotropic conductive particles 114 and the anisotropic conductive particles 114 reduce the bonding pressure necessary for the formation of the intermetallic structures 400.

In one embodiment, the intermetallic structures 400 are of silver and copper.

It has been discovered that when using this process there is over a 40% reduction in manufacturing costs when using copper wire compared to using gold wire. Further, the process does not require bonding to be performed in an inert gas.

It has been discovered that this provides for a low thermal budget, especially when starting with the substrate 200 in the wafer stage.

Further, it has been discovered that the B-stage polymer 112 can be used with a copper bond pad, which does not have to be plated as in a conventional copper wire bonding process.

Still further, it has been discovered that the process is compatible with low-K dielectric materials.

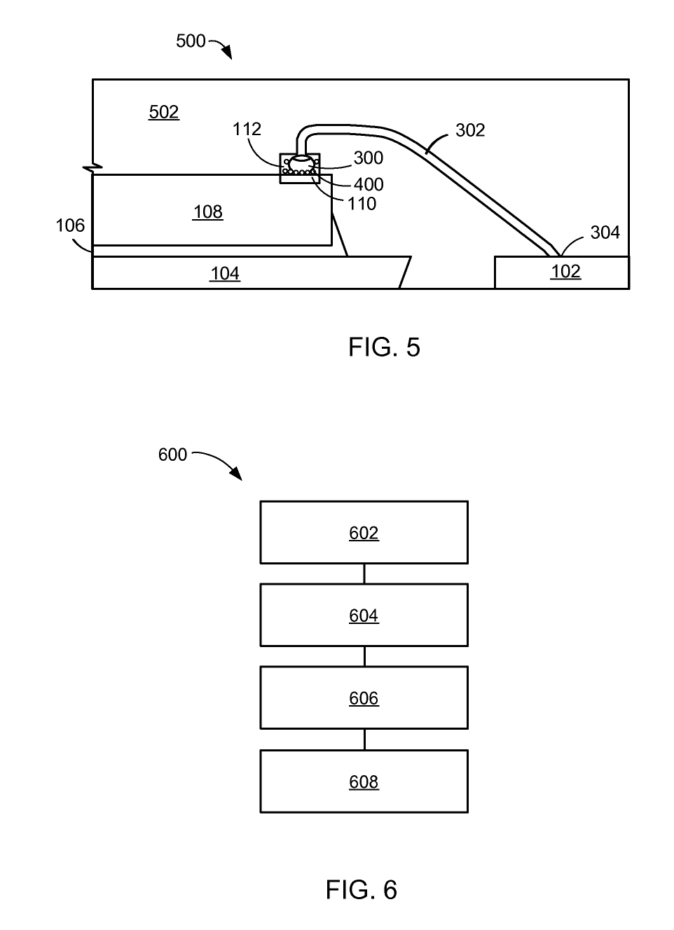

Referring now to FIG. 5, therein is shown a cross-sectional view of a completed integrated circuit packaging system in the embodiment of the present invention.

A partial completed integrated circuit packaging system 500 has an encapsulant 502 protecting the die 108, the bond wire 302, and the stitch bond 304.

Referring now to FIG. 6, therein is shown a flow chart of a method of manufacture of an integrated circuit packaging system in an embodiment of the present invention. The method 600 includes: providing a substrate having a bond pad in a block 602; depositing a B-stage polymer, having a dispersion of conductive particles therein, on the bond pad in a block 604; inserting a bond ball into the B-stage polymer in a block 606, and forming intermetallic structures between the bond ball and the bond pad in a block 608.

The resulting method, process, apparatus, device, product, and/or system is straightforward, cost-effective, uncomplicated, highly versatile, accurate, sensitive, and effective, and can be implemented by adapting known components for ready, efficient, and economical manufacturing, application, and utilization.

Another important aspect of the present invention is that it valuably supports and services the historical trend of reducing costs, simplifying systems, and increasing performance.

These and other valuable aspects of the present invention consequently further the state of the technology to at least the next level.

While the invention has been described in conjunction with a specific best mode, it is to be understood that many alternatives, modifications, and variations will be apparent to those skilled in the art in light of the aforegoing description. Accordingly, it is intended to embrace all such alternatives, modifications, and variations that fall within the scope of the included claims. All matters hithertofore set forth herein or shown in the accompanying drawings are to be interpreted in an illustrative and non-limiting sense.

What is claimed is:

1. A method of manufacture of an integrated circuit packaging system comprising:
providing a substrate having a bond pad;
depositing a B-stage polymer, having a dispersion of conductive particles therein, on the bond pad;
inserting a bond ball into the B-stage polymer; and
forming intermetallic structures between the bond ball and the bond pad.

2. The method as claimed in claim 1 wherein depositing the B-stage polymer deposits an ultraviolet light or heat curable polymer.

3. The method as claimed in claim 1 wherein depositing the B-stage polymer having a dispersion of conductive particles deposits anisotropic conductive particles.

4. The method as claimed in claim 1 wherein:
inserting the bond ball into the B-stage polymer occurs with the B-stage polymer in the B-stage thereof.

5. The method as claimed in claim 1 further comprising:
bonding the bond ball to the bond pad and the forming of intermetallic structures occurs under heat and friction.

6. A method of manufacture of an integrated circuit packaging system comprising:
providing a die having a bond pad;
depositing a B-stage adhesive, having a dispersion of conductive particles therein, on the bond pad;
inserting a bond ball into the B-stage adhesive in the B-stage; and
forming intermetallic structures between the bond ball and the bond pad from the conductive particles.

7. The method as claimed in claim 6 wherein depositing the B-stage adhesive includes application of an ultra-violet radiation dosage of 0.7 J/cm² UVA or 0.5 J/cm² UAV or a thermal cure from about 45 to 60 minutes at 150° C.

8. The method as claimed in claim 6 wherein depositing the B-stage adhesive having a dispersion of conductive particles uses coated beads.

9. The method as claimed in claim 6 wherein:
inserting the bond ball into the B-stage adhesive occurs during wire bonding from the B-stage adhesive to a lead or in a reverse stitch stand-off bumping process.

10. The method as claimed in claim 6 wherein:
forming of the intermetallic structures occurs under heat and ultrasonic bonding.

11. An integrated circuit packaging system comprising:
a substrate having a bond pad;
a B-stage polymer, having a dispersion of conductive particles therein, on the bond pad; and
a bond ball inserted into the B-stage polymer for forming intermetallic structures between the bond ball and the bond pad.

12. The system as claimed in claim 11 wherein the B-stage polymer is an ultraviolet light or heat curable polymer.

13. The system as claimed in claim 11 wherein the B-stage polymer has a dispersion of conductive particles which are anisotropic conductive particles.

14. The system as claimed in claim 11 wherein:
the bond ball is in the B-stage polymer in the B-stage thereof.

15. The system as claimed in claim 11 wherein:
the intermetallic structures are formed over a low dielectric constant material.

16. The system as claimed in claim 11 wherein:
the B-stage polymer is a B-stage adhesive in the B-stage; and
the intermetallic structures are formed from the conductive particles.

17. The system as claimed in claim 16 wherein the B-stage adhesive is capable of transition into a B-stage by an ultra-violet radiation dosage of 0.7 J/cm² UVA or 0.5 J/cm² UAV or a thermal cure from about 45 to 60 minutes at 150° C.

18. The system as claimed in claim 16 wherein the B-stage adhesive has a dispersion of conductive particles of coated beads.

19. The system as claimed in claim 16 further comprising:
a bond wire between the B-stage adhesive on the bond pad and a lead.

20. The system as claimed in claim 16 wherein:
the intermetallic structures are sandwiched between the bond ball and the bond pad.
